(19) United States
(12) Patent Application Publication
(10) Pub. No.: US 2025/0311525 A1
(43) Pub. Date: Oct. 2, 2025

(54) Imaging Element and Method Of Manufacturing the Same, and Electronic Apparatus

(71) Applicant: SONY SEMICONDUCTOR SOLUTIONS CORPORATION, Kanagawa (JP)

(72) Inventors: Kazunobu OTA, Tokyo (JP); Mitsuru SATO, Kanagawa (JP); Toshifumi WAKANO, Kanagawa (JP)

(73) Assignee: SONY SEMICONDUCTOR SOLUTIONS CORPORATION, Kanagawa (JP)

(21) Appl. No.: 19/239,286

(22) Filed: Jun. 16, 2025

Related U.S. Application Data
(62) Division of application No. 15/554,630, filed on Aug. 30, 2017.

(51) Int. Cl. H10K 39/32; H01L 21/768; H01L 23/48; H04N 25/70; H04N 25/704; H10F 39/00; H10F 39/12

(52) U.S. Cl. CPC H10K 39/32; H01L 21/76898; H01L 23/481; H04N 25/70; H04N 25/704; H10F 39/191; H10F 39/199; H10F 39/802; H10F 39/8037; H10F 39/812; H10F 39/8057

(57) ABSTRACT

The present technology relates to a back surface irradiation type imaging element having an organic photoelectric conversion film capable of preventing color mixing and securing dynamic range, a method of manufacturing the same, and an electronic apparatus. An imaging element according to an aspect of the present technology includes a photoelectric conversion film provided on one side of a semiconductor substrate, a pixel separation section formed in an inter-pixel region, and a through electrode that transmits a signal, corresponding to an electric charge obtained by photoelectric conversion in the photoelectric conversion film, to a wiring layer formed on the other side of the semiconductor substrate, the through electrode being formed in the inter-pixel region. The present technology is applicable to a back surface irradiation type CMOS image sensor.

### CROSS REFERENCE TO RELATED APPLICATIONS

This application is a divisional application of U.S. patent application Ser. No. 15/554,630 filed Aug. 30, 2017, which is a national stage application under 35 U.S.C. 371 and claims the benefit of PCT Application No. PCT/JP2016/055567 having an international filing date of Feb. 25, 2016, which designated the United States, which PCT application claimed the benefit of Japanese Patent Application No. 2015-045906 filed Mar. 9, 2015, the disclosures of which are incorporated herein by reference in their entirety.

### Technical Field

The present technology relates to an imaging element and a method of manufacturing the same, and an electronic apparatus. Particularly, the present technology relates to an imaging element of a back surface irradiation type that has an organic photoelectric conversion film, in which color mixing can be prevented and a dynamic range can be secured, a method of manufacturing the same, and an electronic apparatus.

### Background Art

There has been known an imaging element of a back surface irradiation type that is irradiated with light from the side opposite to the side on which a wiring layer is formed on a semiconductor substrate. PTL 1 discloses that an imaging element having little false color and a high resolution can be realized by combining an imaging element of the back surface irradiation type with an organic film having a photoelectric conversion function.

The imaging element described in PTL 1 has a structure in which an organic photoelectric conversion film is stacked in a layer upper than a back surface (the light incidence side) of a semiconductor substrate. An electric charge obtained by photoelectric conversion in the organic photoelectric conversion film is transferred to a wiring layer at a front surface through a through electrode formed to penetrate the semiconductor substrate. A reading-out element such as an amplifier transistor is provided in the wiring layer.

PTL 2 discloses a technology of forming a pixel separation section by embedding an insulating film in an inter-pixel region which is a region between pixels of an imaging element of a back surface irradiation type. With each pixel electrically separated, so-called “color mixing” in which light and/or electrons leak in from the adjacent pixels can be prevented from occurring.

### CITATION LIST

### Patent Literatures

### [PTL 1]

JP 2011-187544 A

### [PTL 2]

JP 2013-175494 A

### SUMMARY

### Technical Problem

In the case of making finer an imaging element that has the aforementioned through electrodes, it is difficult to simultaneously realize both prevention of color mixing and securement of a dynamic range (electric charge accumulation amount), among imaging characteristics. If a pixel separation section is provided between pixels in order to prevent color mixing, a region for a photodiode would be narrowed and it would be impossible to secure a dynamic range.

The present technology has been made in consideration of the above-mentioned circumstances. It is an object of the present technology to ensure that color mixing can be prevented and a dynamic range can be secured, in an imaging element of a back surface irradiation type that has an organic photoelectric conversion film.

### Solution to Problem

An imaging element according to an aspect of the present technology includes pixels, the pixels each having a photoelectric conversion film provided on one side of a semiconductor substrate, a pixel separation section formed in an inter-pixel region, and a through electrode that transmits a signal, corresponding to an electric charge obtained by photoelectric conversion in the photoelectric conversion film, to a wiring layer formed on another side of the semiconductor substrate, the through electrode being formed in the inter-pixel region.

The pixel separation section and the through electrode may be formed in such a manner that an insulating film of the pixel separation section and an insulating film covering a periphery of the through electrode make contact with each other.

The through electrode may be connected to a reading-out element in the wiring layer through a polysilicon electrode formed on an element separation section formed in the semiconductor substrate.

A silicide may be provided at an upper portion of the polysilicon electrode.

A high-dielectric-constant gate insulating film may be provided between the through electrode and the polysilicon electrode.

The through electrode may be formed by embedding an impurity-doped polysilicon, which is a material for the polysilicon electrode, in a through-hole, at the time of forming the polysilicon electrode.

The pixel separation section may be formed in such a manner that the insulating film of the pixel separation section and the insulating film covering the periphery of the through electrode make contact with each other, at the time of processing on the one side.

The through electrode formed from the impurity-doped polysilicon may be connected to an electrode of the photoelectric conversion film through an electrode plug, and a high-dielectric-constant gate insulating film may be provided between the through electrode and the electrode plug.

A light-shielding film that covers part of a light receiving region of the pixel which is a phase difference detection pixel may further be provided. In this case, an upper end portion of the through electrode may be formed in such a manner as to cover a range including an upper side of the insulating film covering the periphery of the through electrode.

A metal may be used as a material for constituting that part of the pixel separation section which does not make contact with the insulating film covering the periphery of the through electrode.

A light-shielding film formed on the pixel separation section may further be provided. In this case, an upper end portion of the through electrode may be formed in such a manner as to cover an upper side of the insulating film covering the periphery of the through electrode and to be separate from the light-shielding film.

A plurality of the through electrodes may be formed in the inter-pixel region between two adjacent ones of the pixels.

### Advantageous Effect of Invention

According to the present technology, color mixing can be prevented and a dynamic range can be secured, in an imaging element of a back surface irradiation type that has an organic photoelectric conversion film.

Note that the effect described here is not necessarily a limitative one, and any of the effects described herein may be ensured.

### BRIEF DESCRIPTION OF DRAWINGS

FIG. 1 is a figure illustrating a configuration example of an imaging element according to an embodiment of the present technology.

FIG. 2 is a figure illustrating pixels in an enlarged form.

FIG. 3 is a sectional view of the imaging element taken along line A-A of FIG. 2.

FIG. 4 is a sectional view of the imaging element taken along line B-B of FIG. 2.

FIG. 5 is a flow chart for explaining a first method of manufacturing an imaging element.

FIG. 6 depicts figures illustrating a state of a semiconductor substrate after a front surface step.

FIG. 7 depicts figures illustrating a state of the semiconductor substrate after an opening pretreatment.

FIG. 8 depicts figures illustrating a state of the semiconductor substrate after dry etching.

FIG. 9 depicts figures illustrating a state of the semiconductor substrate after removal of a resist.

FIG. 10 depicts figures illustrating a state of the semiconductor substrate after formation of an anti-reflection film.

FIG. 11 depicts figures illustrating the semiconductor substrate after formation of an insulating film.

FIG. 12 depicts figures illustrating a state of the semiconductor substrate after a through-hole formation pretreatment.

FIG. 13 depicts figures illustrating a state of the semiconductor substrate after dry etching.

FIG. 14 depicts figures illustrating a state of the semiconductor substrate after removal of a resist.

FIG. 15 depicts figures illustrating a state of the semiconductor substrate after formation of a through electrode.

FIG. 16 depicts figures illustrating a state of the semiconductor substrate after an upper end portion formation pretreatment.

FIG. 17 depicts figures illustrating a state of the semiconductor substrate after dry etching.

FIG. 18 depicts figures illustrating a state of the semiconductor substrate after removal of a resist.

FIG. 19 is a figure illustrating a state of the semiconductor substrate after other back surface steps.

FIG. 20 is a figure illustrating another configuration example of a pixel.

FIG. 21 is a figure illustrating a further configuration example of the pixel.

FIG. 22 is a figure illustrating a modification of a section of the imaging element.

FIG. 23 is a figure illustrating an example of a phase difference detection pixel.

FIG. 24 is a figure illustrating an example of layout of a light-shielding film of the phase difference detection pixel.

FIG. 25 is a figure illustrating a modification of a section of the imaging element.

FIG. 26 is a block diagram illustrating a configuration example of an electronic apparatus that has the imaging element.

FIG. 27 is a figure illustrating usage examples in which an imaging element is used.

### DESCRIPTION OF EMBODIMENTS

Modes for carrying out the present technology will be described below. The description will be made in the following order.
1. Configuration Example of Imaging Element
2. Detailed Structure of Pixel
3. First Manufacturing Method
4. Second Manufacturing Method
5. Example of Layout of Through Electrode
6. Modifications

### 1. Configuration Example of Imaging Element

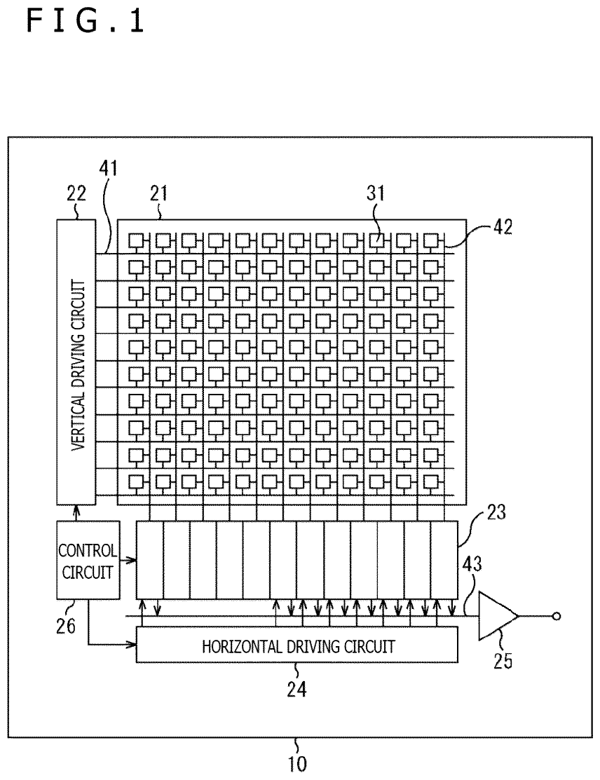

FIG. 1 is a figure illustrating a configuration example of an imaging element according to an embodiment of the present technology.

An imaging element 10 is an imaging element such as a complementary metal oxide semiconductor (CMOS) image sensor. The imaging element 10 receives incident light from a subject through an optical lens, converts the received light into an electrical signal, and outputs a pixel signal.

As will be described later, the imaging element 10 is a back surface irradiation type imaging element in which where a surface at which to form a wiring layer is a front surface of a semiconductor substrate, irradiation with light takes place from a back surface opposite to the front surface. Each of pixels constituting the imaging element 10 is provided with an organic film having a photoelectric conversion function, in a layer upper than the semiconductor substrate.

The imaging element 10 includes a pixel array section 21, a vertical driving circuit 22, a column signal processing circuit 23, a horizontal driving circuit 24, an output circuit 25, and a control circuit 26.

In the pixel array section 21, pixels 31 are arranged in a two-dimensional array. The pixel 31 has a photoelectric conversion film and a photo diode (PD) as a photoelectric conversion element, and a plurality of pixel transistors.

The vertical driving circuit 22 includes, for example, a shift register. The vertical driving circuit 22 is so configured that by supplying pulses for driving the pixels 31 to a predetermined pixel driving wire 41, the pixels 31 are driven on a row basis. The vertical driving circuit 22 sequentially scans the respective pixels 31 in the pixel array section 21 in a vertical direction on a row basis, and supplies the column signal processing circuits 23 with a pixel signal according to signal charges obtained in the respective pixels 31, through vertical signal lines 42.

The column signal processing circuits 23 are arranged on the basis of each column of the pixels 31, and process the signals outputted from the pixels 31 for one row, on a pixel column basis. For instance, the column signal processing circuits 23 perform signal processing such as correlated double sampling (CDS) for removal of fixed pattern noises intrinsic of the pixels, analog-digital (AD) conversion, etc.

The horizontal driving circuit 24 includes, for example, a shift register. By sequentially outputting horizontal scanning pulses, the horizontal driving circuit 24 sequentially selects the column signal processing circuits 23, and causes pixel signals to be outputted to a horizontal signal line 43.

The output circuit 25 applies signal processing to signals supplied from the respective column signal processing circuits 23 through the horizontal signal line 43, and outputs the signals obtained by the signal processing. The output circuit 25 may perform only buffering, or may perform black level adjustment, column variability correction, various kinds of digital signal processing and the like.

The control circuit 26 outputs a clock signal and control signals to the vertical driving circuit 22, the column signal processing circuits 23, and the horizontal driving circuit 24, and controls operations of the sections.

### 2. Detailed Structure of Pixel

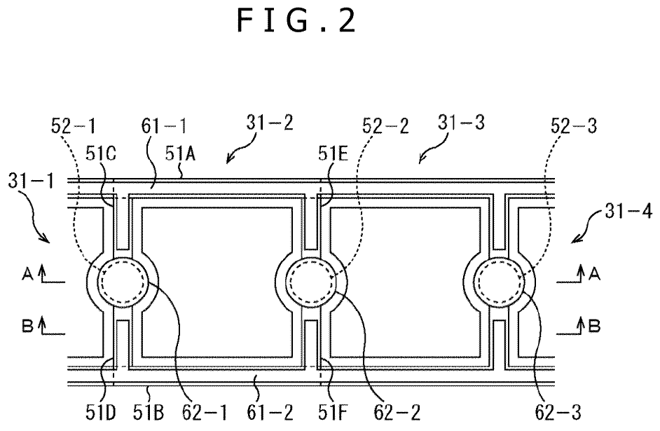

FIG. 2 is a figure illustrating the pixels 31 in an enlarged form.

FIG. 2 depicts the whole of pixels 31-2 and 31-3 which are two adjacent pixels 31, a part of a pixel 31-1 which is adjacent to the pixel 31-2, and a part of a pixel 31-4 which is adjacent to the pixel 31-3. The configuration depicted in FIG. 2 is not a configuration appearing directly on the back surface side of the imaging element 10, and a configuration such as an organic photoelectric conversion film is stackedly provided on this configuration. In other words, FIG. 2 is not a plan view of the pixels 31, but is a figure illustrating a state of the configuration of predetermined layers of the pixels 31 as viewed from the back surface side. While the configuration around the pixel 31-2 will be described primarily, the description applies also to the other pixels.

In an inter-pixel region which is a region between the pixel 31-2 and a pixel 31 adjacent to and on the upper side the pixel 31-2, there is formed a pixel separation section 51A. The pixel separation section 51A is configured by providing an insulating film or the like in a groove which has a predetermined depth and a substantially constant width. The other pixel separation sections also have similar configuration. By the pixel separation section 51A, the pixel 31-2 and the pixel 31 adjacent to and on the upper side of the pixel 31-2 are electrically separated from each other.

Similarly, a pixel separation section 51B is formed in an inter-pixel region between the pixel 31-2 and a pixel 31 adjacent to and on the lower side of the pixel 31-2. By the pixel separation section 51B, the pixel 31-2 and the pixel 31 adjacent to and on the lower side of the pixel 31-2 are electrically separated from each other.

In an inter-pixel region between the pixel 31-2 and a pixel 31-1 adjacent to and on the left side of the pixel 31-2, there are formed a pixel separation section 51C on the upper side and a pixel separation section 51D on the lower side, with a through-hole 52-1 therebetween. The diameter of the through-hole 52-1 is slightly greater than the width of the pixel separation sections 51C and 51D.

As will be described later, an electrode material is filled into the through-hole 52-1, to form a through electrode. The periphery of the through electrode is covered with an insulating film. The through electrode formed in the through-hole 52-1 is an electrode for transmitting a signal, according to an electric charge obtained by photoelectric conversion in the organic photoelectric conversion film of the pixel 31-2, to a wiring layer of the pixel 31-2.

In this example, one pixel 31 is provided with the organic photoelectric conversion film in an amount for one color, for example, green. One pixel 31 has one through electrode. Blue light and red light are detected by PDs provided on the semiconductor substrate.

The insulating films of the pixel separation sections 51C and 51D and the insulating film covering the periphery of the through electrode formed in the through-hole 52-1 are formed integrally and in contact with one another. The pixel 31-2 and the pixel 31-1 on the left side thereof are electrically separated from each other, by the pixel separation sections 51C and 51D and the insulating film covering the periphery of the through electrode formed in the through-hole 52-1.

In the inter-pixel region between the pixel 31-2 and the pixel 31-3 adjacent to and on the right side of the pixel 31-2, there are formed a pixel separation section 51E on the upper side and a pixel separation section 51F on the lower side, with a through-hole 52-2 therebetween. The diameter of the through-hole 52-2 is slightly greater than the width of the pixel separation sections 51E and 51F.

Similarly to the through-hole 52-1, the through-hole 52-2 is formed therein with a through electrode, the periphery of which is covered with an insulating film. The through electrode formed in the through-hole 52-2 is an electrode for transmitting a signal, according to an electric charge obtained by photoelectric conversion in the organic photoelectric conversion film of the pixel 31-3, to a wiring layer of the pixel 31-3.

The insulating films of the pixel separation sections 51E and 51F and the insulating film covering the periphery of the through electrode formed in the through-hole 52-2 are formed integrally and in contact with one another. The pixel 31-2 and the pixel 31-3 on the right side thereof are electrically separated from each other, by the pixel separation sections 51E and 51F and the insulating film covering the periphery of the through electrode formed in the through-hole 52-2.

A light-shielding film 61-1 is disposed on the pixel separation sections 51A, 51C, and 51E, and a light-shielding film 61-2 is disposed on the pixel separation sections 51B, 51D, and 51F.

The diameter of an upper end portion 62-1 of the through electrode formed in the through-hole 52-1 is greater than the diameter of the through-hole 52-1. The upper end portion 62-1 covers from above the insulating film covering the periphery of the through electrode formed in the through-hole 52-1, and thereby functions as a light-shielding film.

The diameter of an upper end portion 62-2 of the through electrode formed in the through-hole 52-2 is greater than the diameter of the through-hole 52-2. The upper end portion 62-2 covers from above the insulating film covering the periphery of the through electrode formed in the through-hole 52-2, and thereby functions as a light-shielding film.

The inside of the pixel separation sections 51A to 51F and the upper end portions 62-1 and 62-2 is a light receiving region of the pixel 31-2. Note that for preventing short-circuit from occurring between the through electrodes, the light-shielding films 61-1 and 61-2 are formed separate from the upper end portion 62-1. Similarly, the light-shielding films 61-1 and 61-2 are formed separate from the upper end portion 62-2.

Thus, in the imaging element 10, the through electrodes are provided in the inter-pixel regions on the left and right sides of each pixel. In addition, the pixel separation sections and the insulating films in the peripheries of the through electrodes together ensure that each pixel is electrically separated from the adjacent pixels.

With each pixel separated optically and electrically from the adjacent pixels, leaking-in of light or electrons from the adjacent pixels (color mixing) can be prevented from occurring.

Besides, with the through electrodes provided in the inter-pixel regions for each pixel, an electron accumulation region in the pixel can be secured to be wide, and a wide dynamic range can be secured. The PD is provided in the electron accumulation region. If the through electrodes are provided in other regions than the inter-pixel regions, the region for the PD would be narrowed accordingly, and the dynamic range would be narrowed accordingly. Such a situation can be avoided by the above-mentioned configuration of the present technology.

Specifically, in the imaging element 10 which is an imaging element of the back surface irradiation type having the organic photoelectric conversion film, color mixing can be prevented, and a dynamic range can be secured.

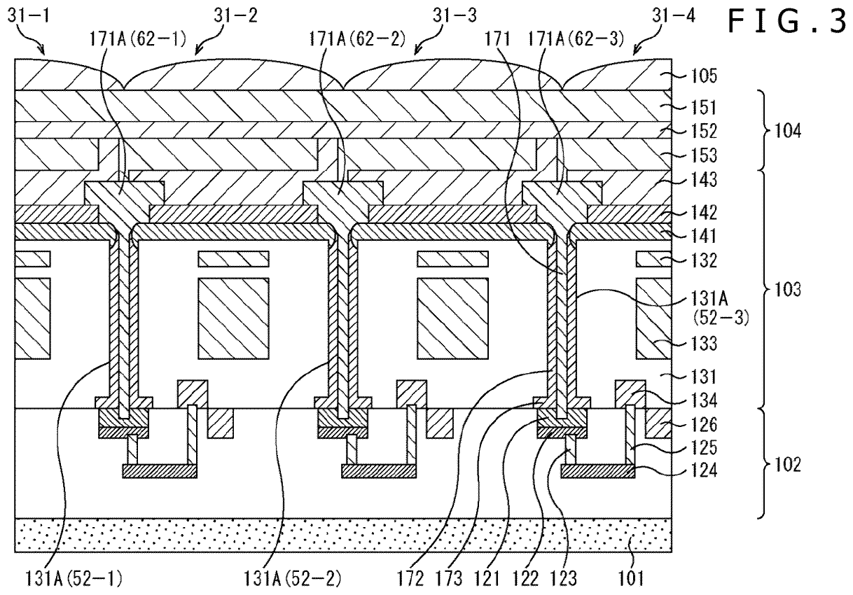

FIG. 3 is a sectional view of the imaging element 10 taken along line A-A of FIG. 2.

As depicted in FIG. 3, a wiring layer 102 and a support substrate 101 are formed on the front surface side (the lower side in FIG. 3) of a semiconductor substrate 131 constituting a light receiving layer 103, and a photoelectric conversion film layer 104 is formed on the back surface side (the upper side in FIG. 3) of the semiconductor substrate 131, with a predetermined layer therebetween. On-chip lenses 105 are provided on the photoelectric conversion film layer 104.

In the wiring layer 102, a polysilicon electrode 121 is formed on a shallow trench isolation (STI) 173 which is an element separation section formed in the semiconductor substrate 131. A silicide 122 is disposed on the polysilicon electrode 121, and the polysilicon electrode 121 and a wiring 124 are connected to each other through the silicide 122 and a contact 123. A floating diffusion (FD) 134 of the semiconductor substrate 131 is connected to the wiring 124 through a contact 125. Reset transistors 126 are provided in the wiring layer 102.

While only a configuration used for transmission of signals, according to electric charges obtained in the organic photoelectric conversion film 152 on the back surface side, to the FDs is depicted as a configuration of the wiring layer 102 in FIG. 3, a configuration used for transmission of signals according to electric charges obtained in the PDs in the silicon substrate is actually provided in addition to selection transistors. The configuration used for transmission of signals includes transfer transistors, reset transistors, amplification transistors, and selection transistors.

The semiconductor substrate 131 in the light receiving layer 103 includes, for example, P-type silicon (Si). PDs 132 and PDs 133 are embedded in the semiconductor substrate 131. For example, the PD 132 is a photoelectric conversion element that mainly receives blue light and performs photoelectric conversion. The PD 133 is a photoelectric conversion element that mainly receives red light and performs photoelectric conversion. FDs 134 are formed on the front surface side of the semiconductor substrate 131.

An anti-reflection film 141 is formed on (on the back surface side) of the semiconductor substrate 131, and insulating films 142 and 143 are formed thereover.

The photoelectric conversion film layer 104 is configured in a stacked form in which the organic photoelectric conversion film 152 is sandwiched between an upper electrode 151 and a lower electrode 153. A voltage is applied on the upper electrode 151, and carriers generated in the organic photoelectric conversion film 152 move toward the lower electrode 153 side. The organic photoelectric conversion film 152 receives, for example, green light and performs photoelectric conversion. The upper electrode 151 and the lower electrode 153 each include, for example, a transparent conductive film such as an indium tin oxide (ITO) film and an indium zinc oxide film.

As for combination of colors, here, the organic photoelectric conversion film 152 is for receiving green light, the PDs 132 are for receiving blue light, and the PDs 133 are for receiving red light, but the combination of colors is arbitrary. For example, the organic photoelectric conversion film 152 may be for receiving red or blue light, and the PDs 132 and the PDs 133 may be for receiving other color lights. Besides, another organic photoelectric conversion film that absorbs light of a color different from that for the organic photoelectric conversion film 152 and performs photoelectric conversion may be stacked in addition to the organic photoelectric conversion film 152, and the PDs in the silicon may be provided in only one layer.

In the inter-pixel region, a through-hole 131A that penetrates the semiconductor substrate 131 is formed. A through electrode 171 is formed in the through-hole 131A, and the periphery of the through electrode 171 is covered with an insulating film 172. An upper end portion 171A of the through electrode 171 is connected to the lower electrode 153. On the other hand, a lower end portion is connected to the polysilicon electrode 121. On the side of the front surface of the semiconductor substrate 131 with respect to the through-hole 131A, an STI 173 is formed integrally with the through-hole 131A.

The through-hole 131A located between the pixel 31-1 and the pixel 31-2 corresponds to the through-hole 52-1 of FIG. 2, and the upper end portion 171A of the through electrode 171 formed in the through-hole 131A located between the pixel 31-1 and the pixel 31-2 corresponds to the upper end portion 62-1 of FIG. 2. In addition, the through-hole 131A located between the pixel 31-2 and the pixel 31-3 corresponds to the through-hole 52-2 of FIG. 2, and the upper end portion 171A of the through electrode 171 formed in the through-hole 131A located between the pixel 31-2 and the pixel 31-3 corresponds to the upper end portion 62-2 of FIG. 2. The through-hole 131A located between the pixel 31-3 and the pixel 31-4 corresponds to the through-hole 52-3 of FIG. 2, and the upper end portion 171A of the through electrode 171 formed in the through-hole 131A located between the pixel 31-3 and the pixel 31-4 corresponds to an upper end portion 62-3 of FIG. 2.

In the pixel 31 having such a configuration, of the light incident on the back surface side of the semiconductor substrate 131, the light having a green wavelength undergoes photoelectric conversion in the organic photoelectric conversion film 152, and an electric charge obtained by the photoelectric conversion is accumulated on the lower electrode 153 side.

Variation in the potential of the lower electrode 153 is transmitted to the wiring layer 102 side through the through electrode 171, and an electric charge according to the variation in the potential is transferred to the FD 134. The amount of the electric charge transferred to the FD 134 is detected by the reset transistor 126, and a signal according to the charge amount thus detected is outputted to the vertical signal line 42 as a green pixel signal through the selection transistor (not depicted) and the like. Thus, the through electrode 171 is connected to a reading-out element through the polysilicon electrode 121.

On the other hand, light having a blue wavelength undergoes photoelectric conversion mainly in the PD 132, and an electric charge obtained by the photoelectric conversion is accumulated. In addition, light having a red wavelength undergoes photoelectric conversion mainly by the PD 133, and an electric charge obtained by the photoelectric conversion is accumulated. The electric charges accumulated in the PD 132 and the PD 133 are transferred to the corresponding FDs, in response to turning-ON of a transfer transistor (not depicted) provided in the wiring layer 102. Signals according to the amounts of the electric charges transferred to the respective FDs are outputted to the vertical signal lines 42 as a blue pixel signal and a red pixel signal, individually, through the amplification transistor, the selection transistor and the like.

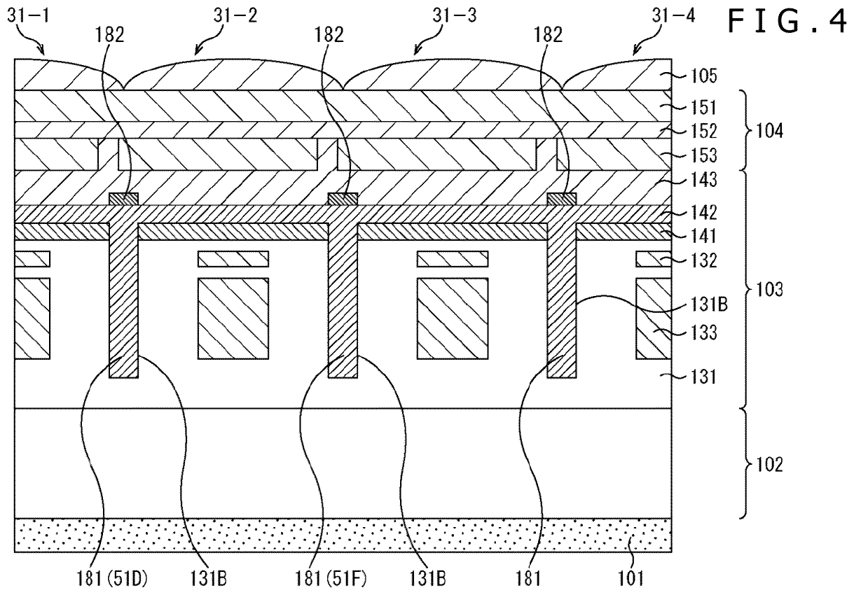

FIG. 4 is a sectional view of the imaging element 10 taken along line B-B of FIG. 2. The same configurations as those described above referring to FIG. 3 are denoted by the same reference symbols as used above. Overlapping descriptions are appropriately omitted.

In the inter-pixel region, a groove 131B is formed. A material constituting an insulating film is filled into the groove 131B, to constitute a pixel separation section 181. Note that a metal can also be used as a material for that portion of the pixel separation section 181 which does not make contact with the insulating film 172 covering the periphery of the through electrode 171.

The pixel separation section 181 formed between the pixel 31-1 and the pixel 31-2 corresponds to the pixel separation section 51D of FIG. 2. In addition, the pixel separation section 181 formed between the pixel 31-2 and the pixel 31-3 corresponds to the pixel separation section 51F of FIG. 2. The pixel separation section 181 formed between the pixel 31-3 and the pixel 31-4 corresponds to the pixel separation section formed under the through-hole 52-3 of FIG. 2. A light-shielding film 182 is formed on each of the pixel separation sections 181.

### 3. First Manufacturing Method

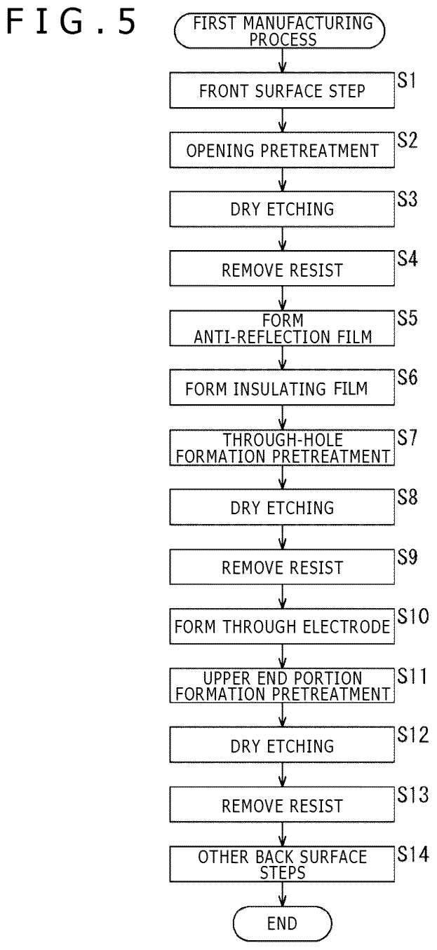

A first method of manufacturing the imaging element 10 including pixels that is configured as above will be described below, referring to a flow chart of FIG. 5. The first manufacturing method is a method in which grooves for pixel separation sections and through-holes for through electrodes are formed in the same step.

In step S1, a front surface step is conducted. The front surface step includes a treatment for forming a wiring layer 102 on a front surface of a semiconductor substrate 131, and a treatment for bonding a support substrate 101. Up to a back surface step, similar treatment to an existing manufacturing treatment of an imaging element of the back surface irradiation type is performed.

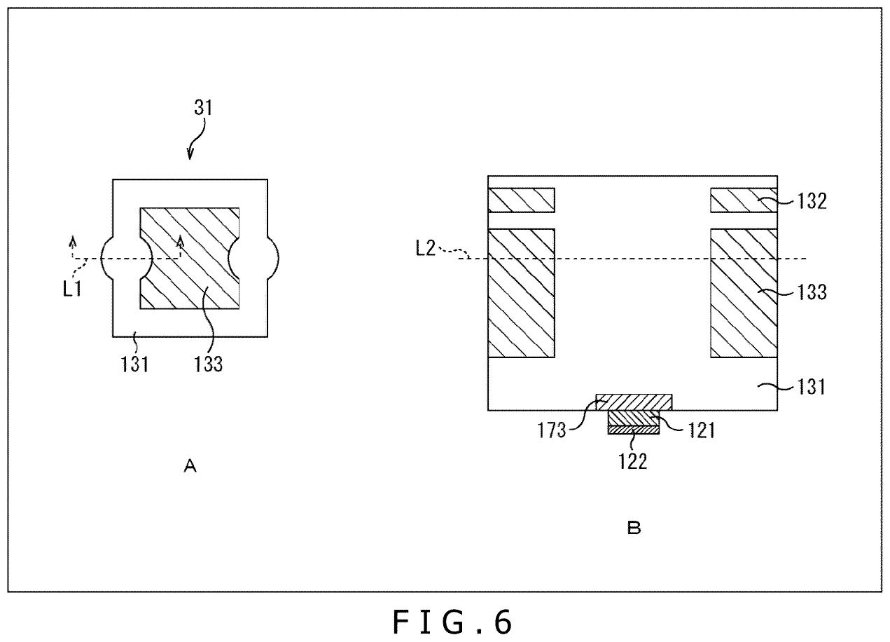

FIG. 6 depicts figures illustrating a state of the semiconductor substrate 131 after the front surface step.

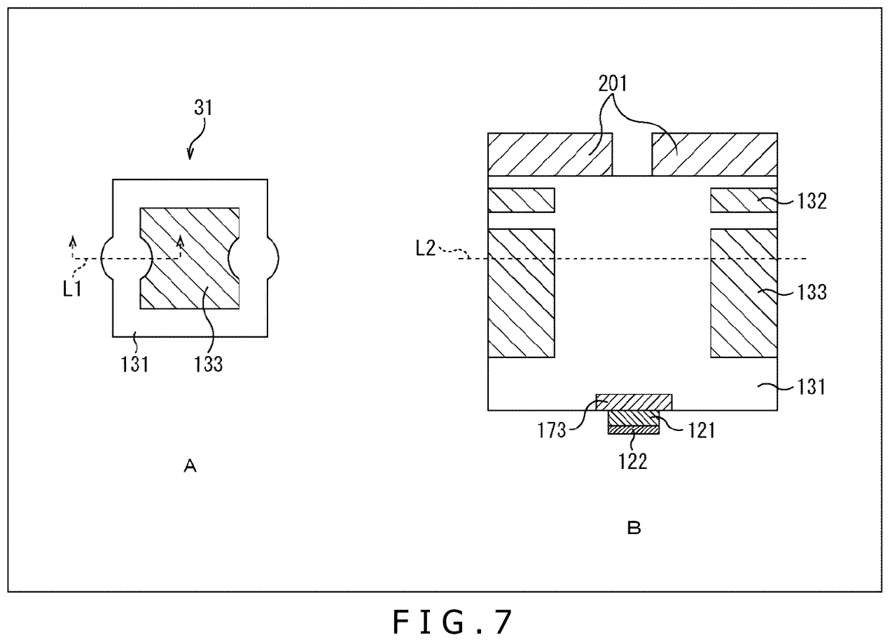

A of FIG. 6 depicts the state, as viewed from the back surface side, of a section in the periphery of one pixel 31 at a level of broken line L2 depicted in B of FIG. 6 at the right side. On the other hand, B of FIG. 6 depicts the state of a section in an inter-pixel region between two pixels 31, at broken line L1 depicted in A of FIG. 6 at the left side. For convenience of explanation, in B of FIG. 6, the support substrate 101 is omitted from the illustration, and only the configuration of part of the wiring layer 102 is depicted. This applies also to FIGS. 7 to 18 described later.

As depicted in B of FIG. 6, after the front surface step, an STI 173 is formed at a position in an inter-pixel region, on a front surface of a P-type doped semiconductor substrate 131. A polysilicon electrode 121 is formed on the STI 173.

An upper surface of the polysilicon electrode 121 may be covered with a silicide 122 which is high in etching ratio with SiO. Examples of the material for the silicide 122 include WSi, TiSi, CoSi₂, and NiSi.

In step S2, an opening pretreatment is conducted. The opening pretreatment includes a treatment for applying a resist for opening through-holes for through electrodes and grooves for pixel separation sections, and then performing exposure to light. The application of the resist and exposure to light are carried out in such a layout that the opening width of the through-holes for through electrodes is greater than the opening width of the grooves for pixel separation sections, as has been described referring to FIG. 2.

FIG. 7 depicts figures illustrating a state of the semiconductor substrate 131 after the opening pretreatment. As depicted in B of FIG. 7, a resist 201 is applied to a back surface of the semiconductor substrate 131 in a layout according to the through-holes for through electrodes and the grooves for pixel separation sections.

In step S3, dry etching is performed. Here, there are selected etching conditions with a high microloading effect such that regions with a higher numerical aperture are etched deeper. For example, the microloading effect is raised under etching conditions with a lowered plasma acceleration voltage and a raised plasma pressure.

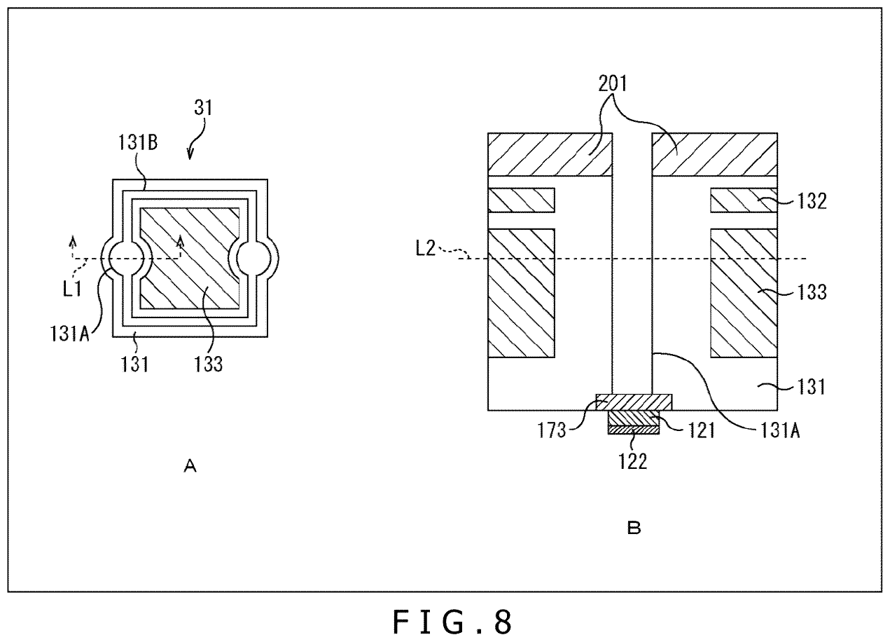

FIG. 8 depicts figures illustrating a state of the semiconductor substrate 131 after the dry etching. As depicted in A of FIG. 8, a through-hole 131A for a through electrode and a groove 131B for a pixel separation section are formed in the periphery of the pixel 31. The through-hole 131A which is a region with a high numerical aperture is formed to penetrate from the back surface of the semiconductor substrate 131 to the STI 173 as depicted in B of FIG. 8, whereas the groove 131B is formed in a shape of having a predetermined depth without penetrating to the front surface of the semiconductor substrate 131.

The through-holes 131A and the grooves 131B may be formed by a method in which the regions for forming the through-holes 131A are preliminarily etched lightly, followed by etching the regions for forming the through-holes 131A and the regions for forming the grooves 131B.

Note that while the groove 131B is formed in a closed shape such as to surround one pixel 31 in A of FIG. 8, the groove 131B actually is formed in a shape of being continuous with the grooves for pixel separation sections of the adjacent pixels.

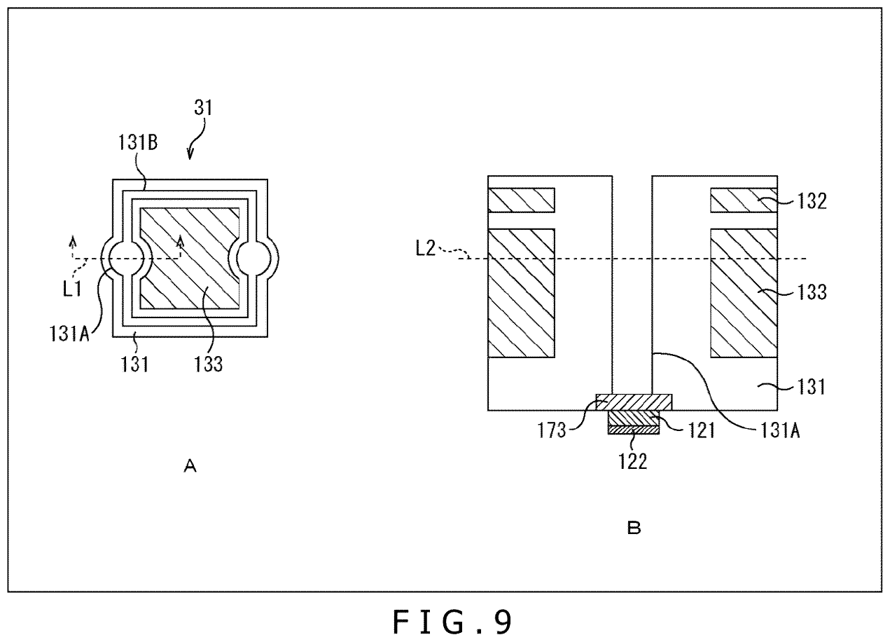

In step S4, the resist is removed. FIG. 9 depicts figures illustrating a state of the semiconductor substrate 131 after removal of the resist 201.

In step S5, an anti-reflection film forming treatment is conducted. The anti-reflection film forming treatment is a treatment for forming an anti-reflection film 141 on the front surface of the semiconductor substrate 131. The formation of the anti-reflection film 141 is conducted by use of a stacking method with high directionality, such as sputtering method, such that the material is not stacked on bottom surfaces of the through-holes 131A and bottom surfaces of the grooves 131B. Examples of the material for the anti-reflection film 141 include SiN, HfO, and TaO.

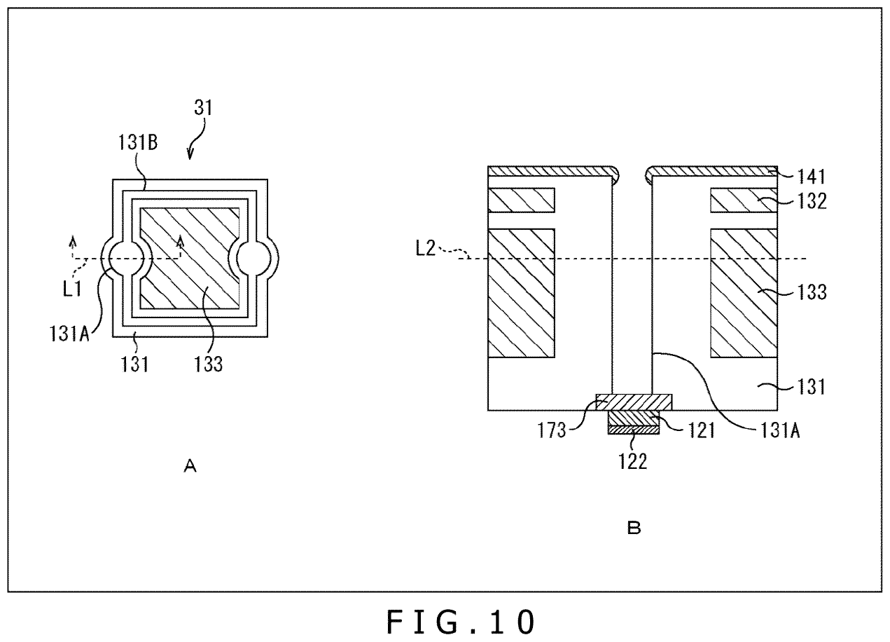

FIG. 10 depicts figures illustrating a state of the semiconductor substrate 131 after the anti-reflection film forming treatment. As depicted in B of FIG. 10, the material is not built up on the bottom surface of the through-hole 131A, and an anti-reflection film 141 is formed on the front surface of the semiconductor substrate 131.

In step S6, an insulating film forming treatment is conducted. The insulating film forming treatment is a treatment for stacking (layering) an insulating film of SiO on the front surface of the semiconductor substrate 131 (on the anti-reflection film 141) and in the inside of the through-holes 131A and the grooves 131B. For example, the insulating film is stacked (layered) by an atomic layer deposition (ALD) method, which is a method with good burying property.

In the case where the material, such as tungsten, used at the time of forming the through electrodes 171 enters, for example, a gap at the groove 131B, short-circuit may occur between the through electrodes 171 of the adjacent pixels. Such a trouble can be prevented by burying the insulating film into the grooves 131B without leaving any gap, by adopting a method with good burying property.

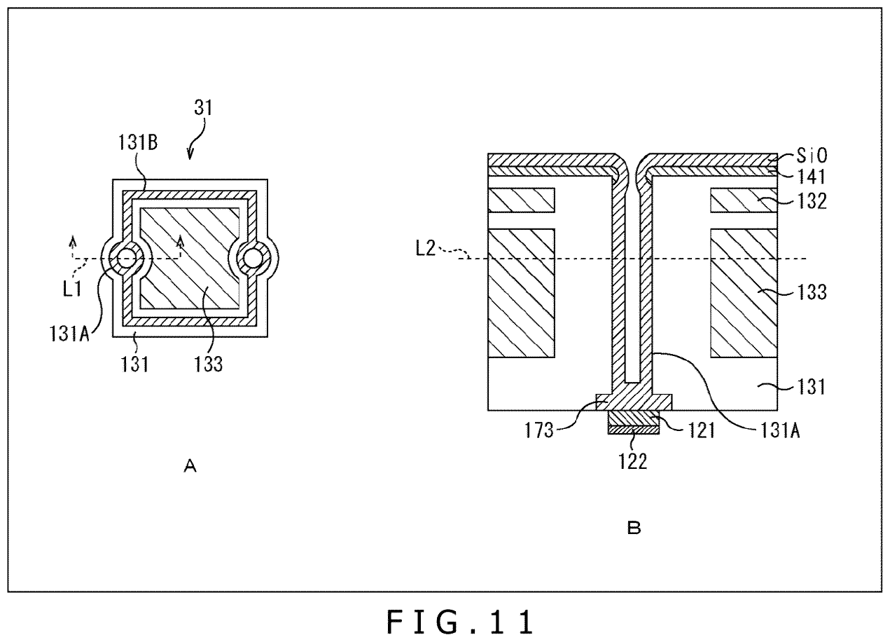

FIG. 11 depicts figures illustrating a state of the semiconductor substrate 131 after the insulating film forming treatment. As depicted in A of FIG. 11, an insulating film of SiO is formed on an inside surface of the through-hole 131A and the whole part of the groove 131B. As depicted in B of FIG. 11, SiO is built up also on the bottom surface of the through-hole 131A.

In step S7, a through-hole formation pretreatment is conducted. The through-hole formation pretreatment is a pretreatment for etching the SiO built up on the bottom surface of the through-hole 131A.

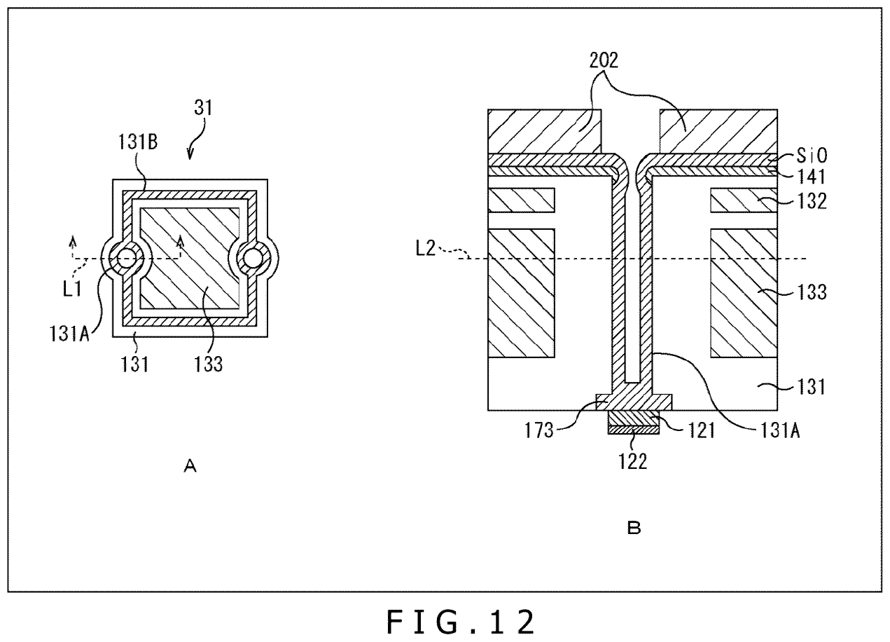

FIG. 12 depicts figures illustrating a state of the semiconductor substrate 131 after the through-hole formation pretreatment. By the through-hole formation pretreatment, a resist 202 having a pattern in which only the vicinity of each through-hole 131A is opened is formed by lithography. In this instance, it is difficult to expose to light the resist in the inside of the through-hole 131A, and, therefore, patterning is conducted using a negative resist.

In step S8, dry etching is conducted. By the dry etching here, the SiO on the bottom surface of the through-hole 131A (the SiO layered by the ALD method or the like in step S6 and the SiO of the STI 173) is removed.

In this instance, for ensuring that the semiconductor substrate 131 in the vicinity of the through-holes 131A is not etched, etching conditions with a high selectivity between SiO and the anti-reflection film 141 (conditions such that the etching rate of SiO is high and the etching rate of the anti-reflection film 141 is low) are selected. For example, etching conditions such that a plasma electric field is weak and that many constituents are etched by chemical reaction are selected. The etching is conducted until the SiO on the bottom surfaces of the through-holes 131A is removed and the polysilicon electrodes 121 are exposed to the inside of the through-holes 131A.

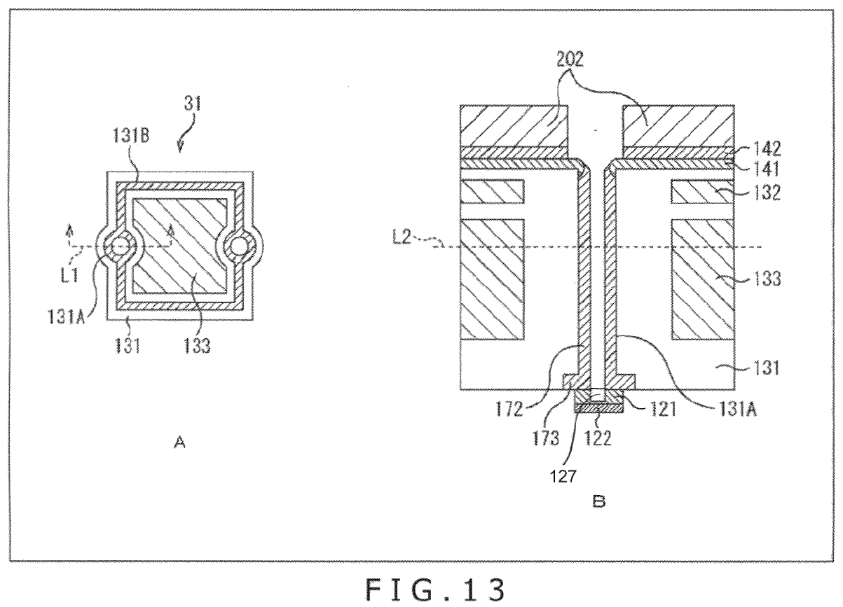

FIG. 13 depicts figures illustrating a state of the semiconductor substrate 131 after the dry etching. As depicted in B of FIG. 13, the SiO on the bottom surface of the through-hole 131A and the SiO in the vicinity of opening of the through-hole 131A are removed. Since the SiO on the bottom surface of the through-hole 131A including the STI 173 is removed, the polysilicon electrode 121 is thereby exposed in the inside of the through-hole 131A. In order to lower the contact resistance between the through electrode 171 and the polysilicon electrode 121, a thin high-k film (a high-dielectric-constant gate insulating film) may be formed at the interface.

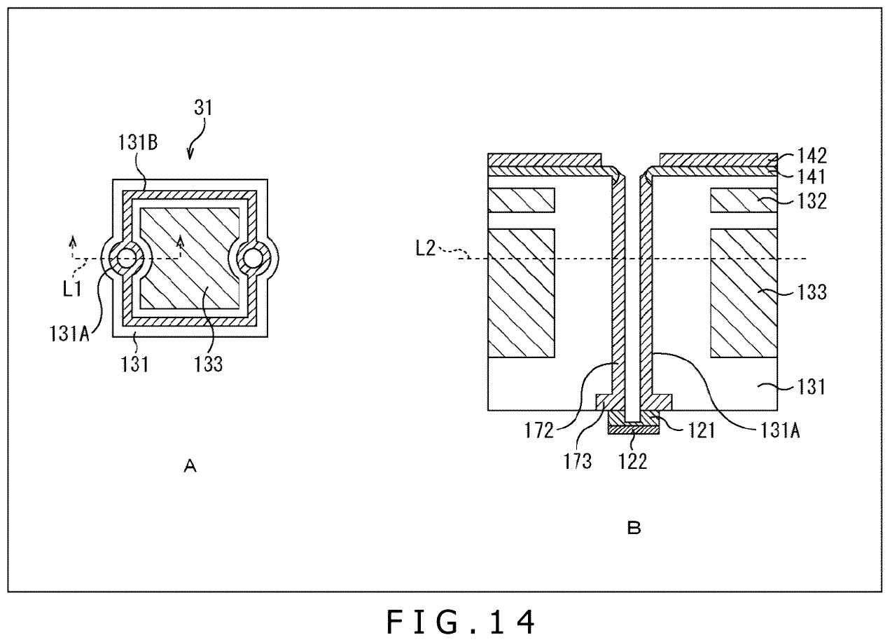

In step S9, the resist is removed. FIG. 14 depicts figures illustrating a state of the semiconductor substrate 131 after the removal of the resist 202.

In step S10, a through electrode forming treatment is conducted. The through electrode forming treatment is a treatment for filling an electrode material for forming the through electrodes 171 into the through-holes 131A. Examples of the electrode material include TiN/W, TaN/Al, and TaN/AlCu.

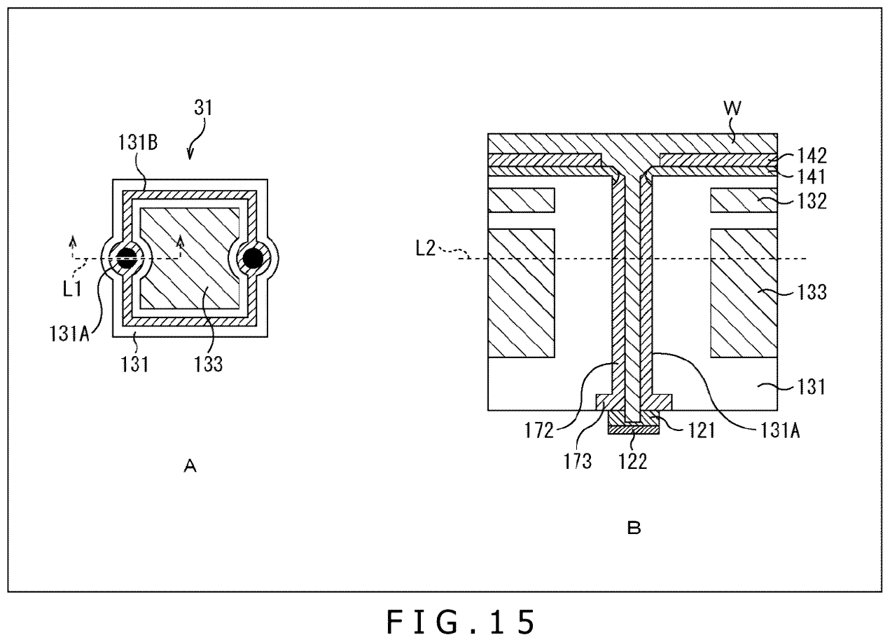

FIG. 15 depicts figures illustrating a state of the semiconductor substrate 131 after the through electrode forming treatment. As depicted in A and B of FIG. 15, the electrode material such as tungsten (W) is filled into the through-holes 131A.

In step S11, an upper end portion formation pretreatment is conducted. The upper end portion formation pretreatment is a pretreatment for forming an upper end portion 171A by etching.

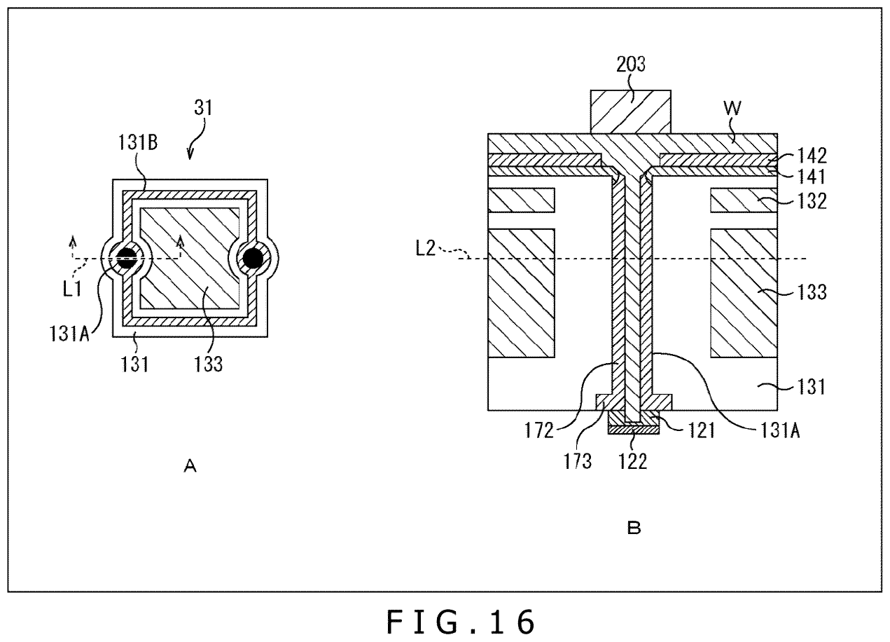

FIG. 16 depicts figures illustrating a state of the semiconductor substrate 131 after the upper end portion formation pretreatment. By lithography in the upper end portion formation pretreatment, a resist 203 having a pattern such as to cover the upper side of the through electrodes 171 is formed.

Note that the electrode material can also be used as a material for forming an inter-pixel light-shielding film, a material for forming a light-shielding film of phase difference detection pixels, or a material for forming a light-shielding film covering reference pixels for black level detection. In this case, the resist 203 is formed at positions where the respective light-shielding films are to be arranged.

In step S12, dry etching is conducted. By the dry etching here, the electrode material in the regions where the resist 203 is absent is removed.

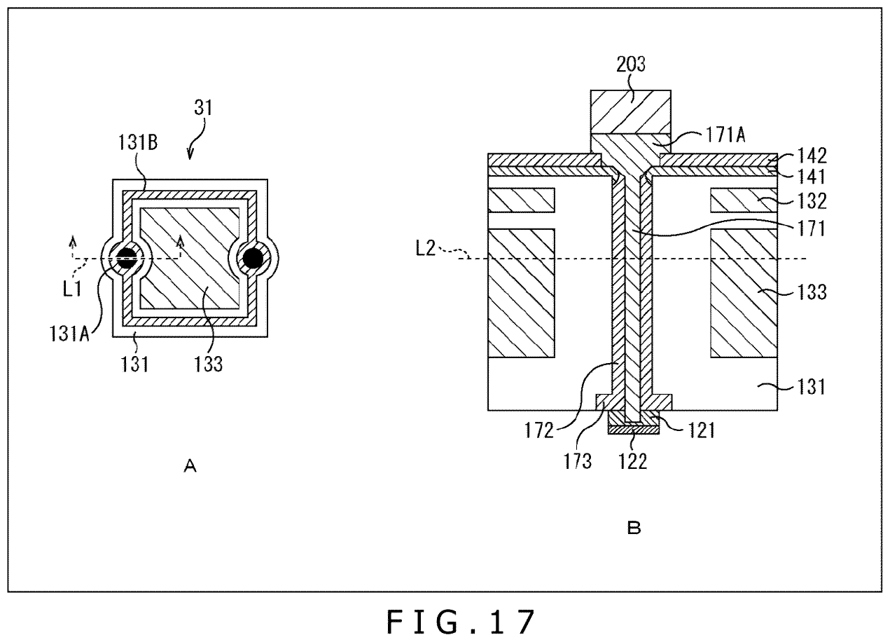

FIG. 17 depicts figures illustrating a state of the semiconductor substrate 131 after the dry etching. As depicted in B of FIG. 17, those portions of the electrode material on the front surface of the semiconductor substrate 131 which are at other positions than the positions where the electrode material is covered with the resist 203 are removed, to form the upper end portions 171A.

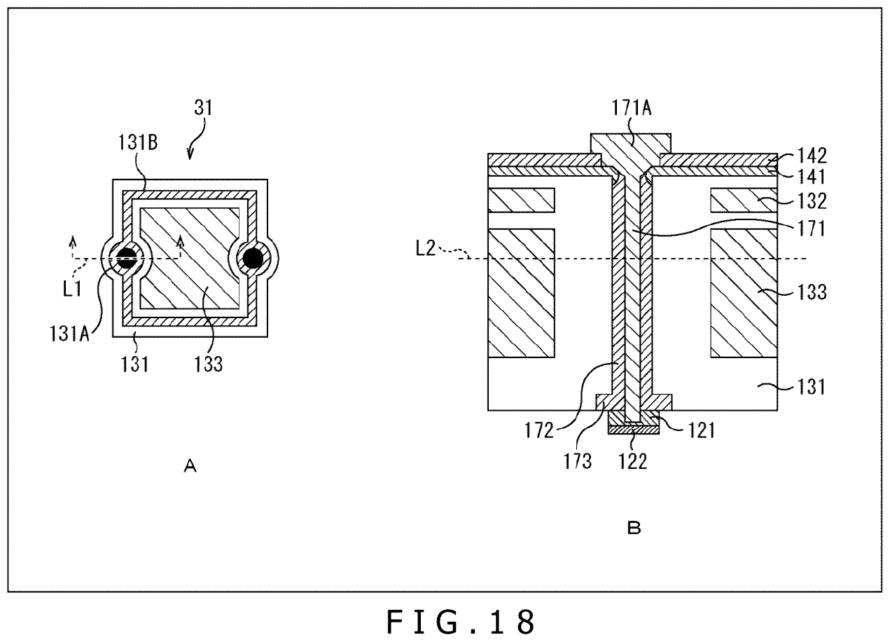

In step S13, the resist is removed. FIG. 18 depicts figures illustrating a state of the semiconductor substrate 131 after the removal of the resist 203.

By the above treatments, the through-holes 131A and the grooves 131B are formed in the same steps, and the through electrodes 171 and the pixel separation sections 181 are formed by filling the through-holes 131A and the grooves 131B with predetermined materials.

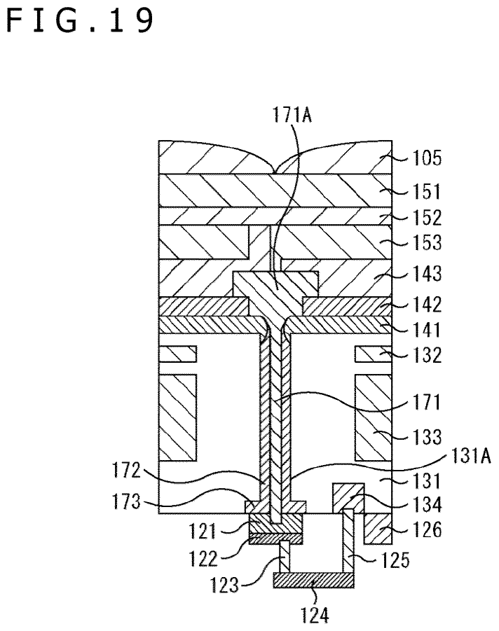

In step S14, other back surface steps for forming other configurations are conducted. By the other back surface steps, an insulating film 143 is formed on the insulating film 142, and a photoelectric conversion film layer 104 is formed on the insulating film 143. After on-chip lenses 105 are formed on the photoelectric conversion film layer 104, the process of manufacturing the pixels 31 is finished. FIG. 19 is a figure illustrating a state of the semiconductor substrate 131 after the other back surface steps.

By the series of treatments as above, it is possible to produce the imaging element 10 of the back surface irradiation type having an organic photoelectric conversion film in which color mixing can be prevented and a dynamic range can be secured.

### 4. Second Manufacturing Method

The through-holes 131A and the grooves 131B can be individually formed in different steps instead of being formed in the same step.

In this case, lithography and etching for forming the through-holes 131A and lithography and etching for forming the grooves 131B are carried out individually. The through-holes 131A may be formed precedingly, or the grooves 131B may be formed precedingly.

After the through-holes 131A and the grooves 131B are individually formed in different steps, isotropic etching such as chemical dry etching (CDE) is applied thereto, whereby the through-holes 131A and the grooves 131B are connected together, and the pixels 31 can each be separated from the adjacent pixels.

### 5. Example of Layout of Through Electrodes

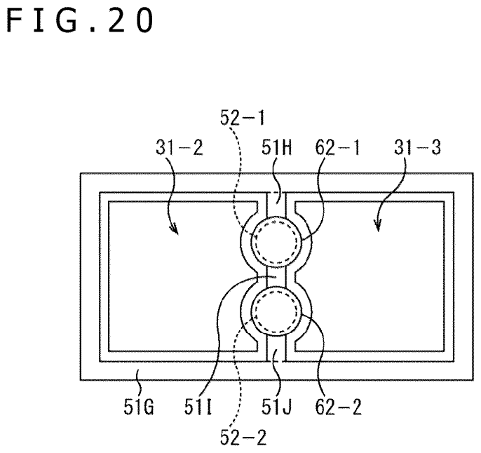

FIG. 20 is a figure illustrating another configuration example of the pixel 31. Of the configurations depicted in FIG. 20, those which are the same as the configurations described above referring to FIG. 2 are denoted by the same reference symbols as used above.

As depicted in FIG. 20, in an inter-pixel region between two adjacent pixels 31, respective through electrodes of the pixels 31 can also be formed in an aligned manner.

In the example of FIG. 20, a pixel separation section 51G is formed in such a manner as to surround a pixel 31-2 and a pixel 31-3. By the pixel separation section 51G, the pixel 31-2 and the pixels 31 adjacent thereto on the upper side, the lower side, and the left side are electrically separated from one another. In addition, by the pixel separation section 51G, the pixel 31-3 and the pixels 31 adjacent thereto on the upper side, the lower side, and the right side are electrically separated from one another.

In the inter-pixel region between the pixel 31-2 and the pixel 31-3, a through-hole 52-1 and a through-hole 52-2 are formed in an aligned manner. A pixel separation section 51H is formed on the upper side of the through-hole 52-1, and a pixel separation section 51I is formed between the through-hole 52-1 and the through-hole 52-2. Besides, a pixel separation section 51J is formed on the lower side of the through-hole 52-2.

The through electrode formed in the through-hole 52-1 is an electrode for transmitting a signal, according to an electric charge obtained by photoelectric conversion in an organic photoelectric conversion film of the pixel 31-2, to a wiring layer of the pixel 31-2. In addition, the through electrode formed in the through-hole 52-2 is an electrode for transmitting a signal, according to an electric charge obtained by photoelectric conversion in an organic photoelectric conversion film of the pixel 31-3, to a wiring layer of the pixel 31-3.

Insulating films of the pixel separation sections 51H, 51I, and 51J and insulating films covering the peripheries of the through electrodes formed in the through-holes 52-1 and 52-2 are formed integrally and connected to one another. The insulating films of the pixel separation sections 51H, 51I, and 51J and the insulating films covering the peripheries of the through electrodes formed in the through-holes 52-1 and 52-2 electrically separate the pixel 31-2 and the pixel 31-3 from each other.

In this way, a plurality of through electrodes can also be formed in one of the inter-pixel regions on the four sides which surround the pixel 31.

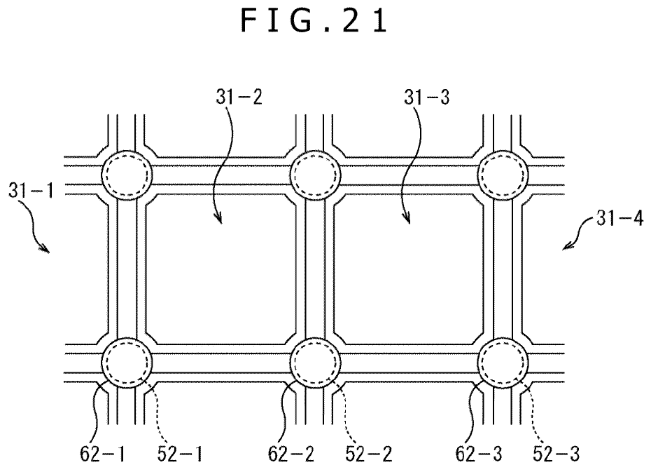

FIG. 21 is a figure illustrating a further configuration example of the pixel 31.

While the through electrode has been formed at a substantially central position in regard of the longitudinal direction in the inter-pixel region of each pixel 31 in the example of FIG. 2, the through electrode may be formed at a position where the inter-pixel regions intersect.

In the example of FIG. 21, through electrodes are formed at the four corners of each pixel 31. A through-hole 52-1 is formed in an inter-pixel region between the pixel 31-2 in FIG. 21 and the pixel 31 located on the left lower side of the pixel 31-2. A through electrode formed in the through-hole 52-1 is an electrode for transmitting a signal, according to an electric charge obtained by photoelectric conversion in an organic photoelectric conversion film of the pixel 31-2, to a wiring layer of the pixel 31-2.

In addition, a through-hole 52-2 is formed in an inter-pixel region between the pixel 31-3 and the pixel 31 located on the left lower side of the pixel 31-3. A through electrode formed in the through-hole 52-2 is an electrode for transmitting a signal, according to an electric charge obtained by photoelectric conversion in an organic photoelectric conversion film of the pixel 31-3, to a wiring layer of the pixel 31-3.

In this way, the through electrodes can also be formed at positions where the inter-pixel regions intersect.

### 6. Modifications

### Modification 1

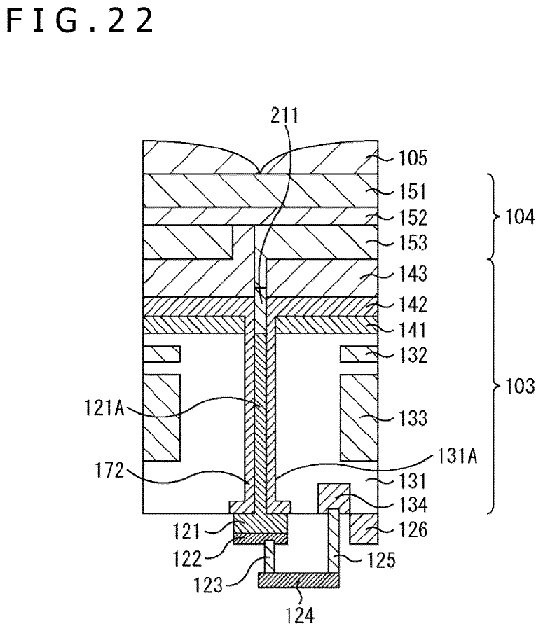

FIG. 22 is a figure illustrating a modification of a section of the imaging element 10. Of the configurations depicted in FIG. 22, those which are the same as the configurations described above referring to FIG. 3 are denoted by the same reference symbols as used above.

In the example of FIG. 22, a through electrode 121A is formed from a polysilicon doped with an impurity. The through electrode 121A is formed integrally with a polysilicon electrode 121. The periphery of the through electrode 121A is covered with an insulating film 172. The through electrode 121A is connected to a lower electrode 153 through an electrode plug 211.

The through electrode 121A is formed, for example, in a front surface step. Specifically, in the front surface step, a through-hole 131A is formed, and SiO as a material for the insulating film 172 is buried in the through-hole 131A. In addition, a through-hole for the through electrode 121A is formed in the SiO buried in the through-hole 131A.

At the time of forming the polysilicon electrode 121, a polysilicon doped with an impurity, which polysilicon is the same as the material for the polysilicon electrode 121, is buried in the through-hole for the through electrode 121A, whereby the through electrode 121A is formed. After the through electrode 121A and the polysilicon electrode 121 are formed, other configurations in a wiring layer 102 and a support substrate 101 are formed in the front surface step.

The electrode plug 211 is formed in a back surface step. In the back surface step, a groove 131B is formed in the manner mentioned above, and an insulating film is buried therein, whereby a pixel separation section 181 is formed. The pixel separation section 181 is formed in such a manner that the insulating film of the pixel separation section 181 and the insulating film 172 covering the periphery of the through electrode 121A make contact with each other.

After an anti-reflection film 141 and an insulating film 142 are formed in the manner mentioned above following to the pixel separation section 181, a groove for the electrode plug 211 is formed, and a material for constituting the electrode plug 211 is buried in the groove. Examples of the material for the electrode plug 211 include Ti/W and Ti/TiN/W. In order to reduce contact resistance, the electrode plug 211 may be formed of a stacked structure of a thin high-k film and tungsten (W).

After the electrode plug 211 is formed, other configurations on the back surface side are formed, whereby the imaging element 10 having the pixels 31 depicted in FIG. 22 is manufactured.

### Modification 2

A phase difference detection pixel constituting the imaging element 10 will be described. The above-mentioned pixel having the through electrode in the inter-pixel region can also be used as the phase difference detection pixel.

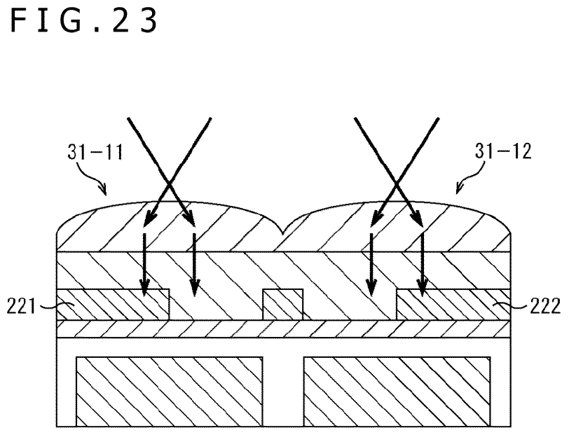

FIG. 23 is a figure illustrating an example of the phase difference detection pixel.

A pixel 31-11 and a pixel 31-12 aligned adjacent to each other are phase difference detection pixels. Approximately one half of the whole part of a light receiving region of the pixel 31-11 which is a phase difference detection pixel is covered with a light-shielding film 221. In addition, approximately one half of the whole part of a light receiving region of the pixel 31-12 is covered with a light-shielding film 222.

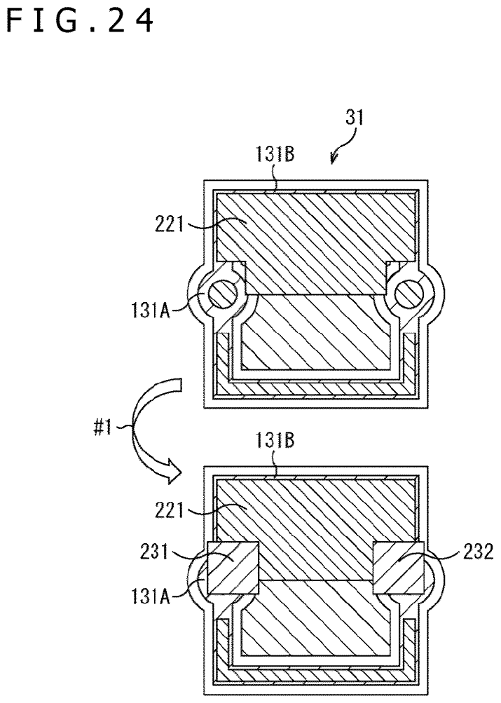

FIG. 24 depicts figures illustrating an example of layout of a light-shielding film of a phase difference detection pixel.

In the top of FIG. 24, of the whole part of a light receiving region of the pixel 31, approximately one upper half exclusive of the vicinities of left and right through-holes 131A is covered with a light-shielding film 221. The vicinities of the through-holes 131A cannot be light-shielded by the light-shielding film 221, and, in this case, phase difference detection performance is deteriorated.

As depicted at the destination of arrow #1, plugs 231 and 232 (light-shielding films) are formed such as to cover the vicinities of the left and right through-holes 131A. The plugs 231 and 232 are formed on upper end portions 171A by use of the same material as the through electrodes 171, for example.

The plug 231 having a substantially square shape in FIG. 24 is formed such that its center position is deviated from the position of the left-side through electrode 171 of the pixel 31. In addition, the plug 232 is formed such that its center position is deviated from the position of the right-side through electrode 171 of the pixel 31. The positions of the plugs 231 and 232 are such positions that a desired phase difference detection performance can be realized.

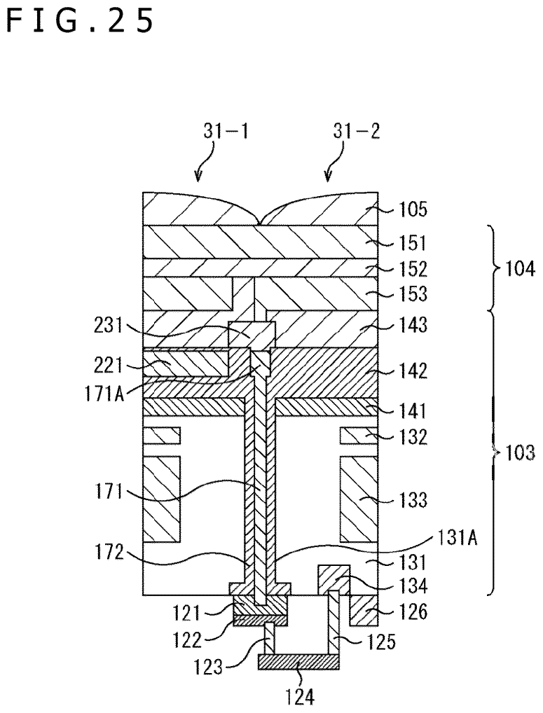

FIG. 25 is a figure illustrating an example of a section of the imaging element 10 having the pixels 31 of FIG. 24. Of the configurations depicted in FIG. 25, those which are the same as the configurations described above referring to FIG. 3 are denoted by the same reference symbols as used above.

In the example of FIG. 25, a light-shielding film 221 is formed in the same layer as an upper end portion 171A of a through electrode 171, in such a manner as to cover part of a light receiving region of a pixel 31-1. The light-shielding film 221 is formed at a position spaced from the upper end portion 171A, in the same step as that in which the through electrode 171 is formed, for example. Note that in the example of FIG. 25, the shape of the upper end portion 171A is different from that depicted in FIG. 3. The shape of the upper end portion 171A can be changed appropriately.

A plug 231 is formed on the upper end portion 171A. The plug 231 has such a shape as to project to the side of the pixel 31-1 where the light-shielding film 221 is formed. With the area between the upper end portion 171A and the light-shielding film 221 thus covered by the plug 231, light can be prevented from entering the pixel 31-1 side through the area between the upper end portion 171A and the light-shielding film 221, and phase difference detection performance can be prevented from being deteriorated.

### Example of Application to Electronic Apparatus

The imaging element 10 can be mounted generally on electronic apparatuses having an imaging element, such as camera modules having an optical lens system and the like, portable terminal devices having an imaging function (for example, smartphones and tablet type terminals), or copying machines using an imaging element in an image reading section.

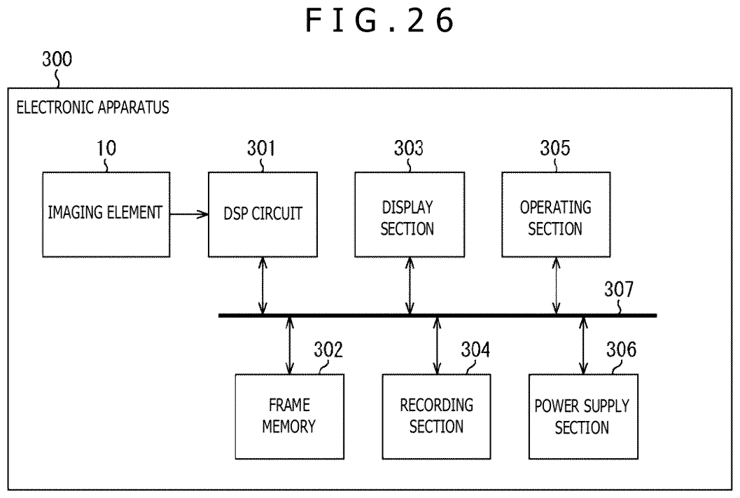

FIG. 26 is a block diagram illustrating a configuration example of an electronic apparatus having an imaging element.

An electronic apparatus 300 of FIG. 26 is an electronic apparatus, for example, an imaging element of a digital still camera or a video camera, a portable terminal device such as a smartphone or a tablet type terminal, or the like.

The electronic apparatus 300 includes an imaging element 10, a digital signal processing (DSP) circuit 301, a frame memory 302, a display section 303, a recording section 304, an operating section 305, and a power supply section 306. The DSP circuit 301, the frame memory 302, the display section 303, the recording section 304, the operating section 305, and the power supply section 306 are interconnected through a bus line 307.

The imaging element 10 takes in incident light (image light) from a subject through an optical lens system (not depicted), converts the amounts of incident light focused to form an image on an imaging plane into electrical signals on a pixel basis, and outputs the electrical signals as pixel signals.

The DSP circuit 301 is a camera signal processing circuit for processing the signals supplied from the imaging element 10. The frame memory 302 temporarily holds image data processed by the DSP circuit 301, on a frame basis.

The display section 303 includes, for example, a panel type display device such as a liquid crystal panel and an organic electro luminescence (EL) panel, and displays a video or still image picked up by the imaging element 10. The recording section 304 records image data of the video or still image picked up by the imaging element 10, on a recording medium such as a semiconductor memory and a hard disk.

The operating section 305 issues operation commands concerning various functions possessed by the electronic apparatus 300, according to user's operations. The power supply section 306 supplies each of the sections with power.

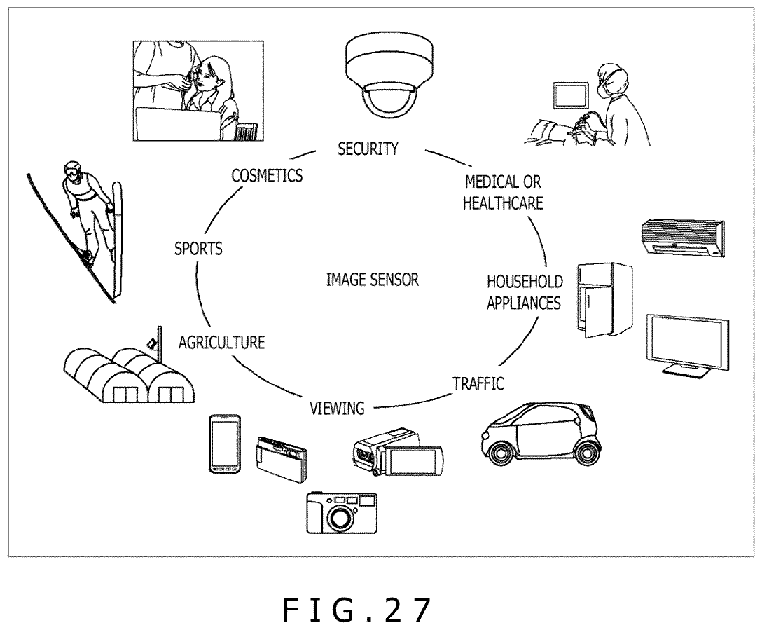

FIG. 27 is a figure illustrating usage examples of the imaging element 10.

The imaging element 10 can be used in various cases of sensing light such as, for example, visible light, infrared light, ultraviolet light, and X-rays as depicted below. Specifically, as depicted in FIG. 27, the imaging element 10 can be used in apparatuses not only in a viewing field in which images for viewing are picked up as aforementioned but also in, for example, a traffic field, a household appliance field, a medical or healthcare field, a security field, a cosmetic field, a sports field, or an agricultural field.

Specifically, as aforementioned, in the viewing field, for example, the imaging element 10 can be used in apparatuses (for example, the electronic apparatus 300 of FIG. 26) for picking up images served to viewing, such as digital cameras, smartphones, and mobile phones provided with a camera function.

In the traffic field, for example, the imaging element 10 can be used in apparatuses served to traffic use, such as in-vehicle sensors for imaging the front side, the rear side, the surroundings, the interior, etc. of an automobile, monitor cameras for monitoring running vehicles or the road, and distance measuring sensors for measuring an inter-vehicle distance for the purposes of safe driving, such as automatic vehicle stop, recognition of the driver's condition, etc.

In the household appliance field, for example, the imaging element 10 can be used in apparatuses served to household appliances such as television sets, refrigerators, and air conditioners for the purpose of imaging a user's gesture and performing an apparatus operation according to the gesture. In addition, in the medical or healthcare field, for example, the imaging element 10 can be used in apparatuses served to medical or healthcare use, such as endoscopes and devices for imaging blood vessels by receiving infrared light.

In the security field, for example, the imaging element 10 can be used in apparatuses served to security use, such as surveillance cameras for security and cameras for person authentification. Besides, in the cosmetic field, for example, the imaging element 10 can be used in apparatuses served to cosmetic use, such as a skin measuring instrument for imaging a skin and a microscope for imaging the scalp.

In the sports field, for example, the imaging element 10 can be used in apparatuses served to sports use, such as action cameras and wearable cameras for sports use or the like. In addition, in the agricultural field, for example, the imaging element 10 can be used in apparatuses served to agricultural use, such as cameras for monitoring conditions of fields and/or farm products.

Note that the embodiments of the present technology are not limited to the above-described embodiments, and various modifications are possible without departing from the scope of the gist of the present technology.

Note that the effects described herein are mere exemplifications and are not limitative, and other effects may be present.

### Examples of Combination of Configurations

The present technology can take the following configurations.
(1)

An imaging element including:
pixels, the pixels each having
   a photoelectric conversion film provided on one side of a semiconductor substrate,
   a pixel separation section formed in an inter-pixel region, and
   a through electrode that transmits a signal, corresponding to an electric charge obtained by photoelectric conversion in the photoelectric conversion film, to a wiring layer formed on another side of the semiconductor substrate, the through electrode being formed in the inter-pixel region.
      (2)

The imaging element as described in (1),
in which the pixel separation section and the through electrode are formed in such a manner that an insulating film of the pixel separation section and an insulating film covering a periphery of the through electrode make contact with each other.
   (3)

The imaging element as described in (1) or (2),
in which the through electrode is connected to a reading-out element in the wiring layer through a polysilicon electrode formed on an element separation section formed in the semiconductor substrate.
   (4)

The imaging element as described in (3),
in which a silicide is provided at an upper portion of the polysilicon electrode.
   (5)

The imaging element as described in (3) or (4),
in which a high-dielectric-constant gate insulating film is provided between the through electrode and the polysilicon electrode.
   (6)

The imaging element as described in (3) or (4),
in which the through electrode is formed by filling, in a through-hole, an impurity-doped polysilicon which is a material for the polysilicon electrode, at the time of forming the polysilicon electrode.
   (7)

The imaging element as described in (6),
in which the pixel separation section is formed in such a manner that an insulating film of the pixel separation section and an insulating film covering a periphery of the through electrode make contact with each other, at the time of processing on the one side.
   (8)

The imaging element as described in (6) or (7),
in which the through electrode formed from the impurity-doped polysilicon is connected to an electrode of the photoelectric conversion film through an electrode plug, and
a high-dielectric-constant gate insulating film is provided between the through electrode and the electrode plug.
   (9)

The imaging element as described in any one of (1) to (8), further including:
receiving region of the pixel which is a phase difference detection pixel,
in which an upper end portion of the through electrode is formed in such a manner as to cover a range including an upper side of an insulating film covering a periphery of the through electrode.
   (10)

The imaging element as described in any one of (1) to (9),
in which a metal is used as a material constituting that part of the pixel separation section which does not make contact with an insulating film covering a periphery of the through electrode.
(11)

The imaging element as described in any one of (1) to (10), further including:
a light-shielding film formed on the pixel separation section,
in which an upper end portion of the through electrode is formed to cover an upper side of an insulating film covering a periphery of the through electrode and to be separate from the light-shielding film.
   (12)

The imaging element as described in any one of (1) to (11),
in which a plurality of the through electrodes are formed in the inter-pixel region between two adjacent ones of the pixels.
   (13)

A method of manufacturing an imaging element, the method including:
a front surface step of forming a configuration including a wiring layer on a semiconductor substrate; and
a back surface step of the semiconductor substrate, the back surface step including the steps of
   forming a groove for forming a pixel separation section in an inter-pixel region, and a through-hole for forming in the inter-pixel region a through electrode that transmits a signal, corresponding to an electric charge obtained by photoelectric conversion in a photoelectric conversion film, to the wiring layer,
forming the pixel separation section in the groove,
forming the through electrode in the through-hole, and
forming the photoelectric conversion film.
   (14)

The method of manufacturing as described in (13),
in which the groove and the through-hole are formed in the same step.
   (15)

The method of manufacturing as described in (13),
in which the groove and the through-hole are formed in different steps.
   (16)

An electronic apparatus including:
an optical section including a lens;
an imaging element that receives light incident thereon through the optical section, the imaging element including pixels, the pixels each having
   a photoelectric conversion film provided on one side of a semiconductor substrate,
   a pixel separation section formed in an inter-pixel region, and
   a through electrode that transmits a signal, corresponding to an electric charge obtained by photoelectric conversion in the photoelectric conversion film, to a wiring layer formed on another side of the semiconductor substrate, the through electrode being formed in the inter-pixel region; and
a signal processing section that processes pixel data outputted from the imaging element.

### REFERENCE SIGNS LIST

10 Imaging element, 31 Pixel, 131 Semiconductor substrate, 171 Through electrode, 181 Pixel separation section

What is claimed is:

1. An imaging element, comprising:
a plurality of pixels;
a photoelectric conversion film provided on one side of a semiconductor substrate;
a pixel separation section formed in an inter-pixel region around a portion of each of the plurality of pixels; and
a through electrode that transmits a signal, corresponding to an electric charge obtained by photoelectric conversion in the photoelectric conversion film, to a wiring layer formed on another side of the semiconductor substrate, the through electrode being formed in the inter-pixel region outside of the pixel separation section,
wherein a first end of the through electrode is connected to a lower electrode of the photoelectric conversion film through an electrode plug, and
wherein the electrode plug has about a same size diameter as the through electrode.

2. The imaging element according to claim 1, wherein the through electrode is formed from a polysilicon with an impurity.

3. The imaging element according to claim 1, wherein the pixel separation section and the through electrode are formed in such a manner that an insulating film of the pixel separation section and an insulating film covering a periphery of the through electrode make contact with each other.

4. The imaging element according to claim 3, wherein the insulating film of the pixel separation section and the insulating film covering a periphery of the through electrode each covers a portion of the electrode plug.

5. The imaging element according to claim 3, further comprising an anti-reflective film provided on the semiconductor substrate.

6. The imaging element according to claim 5, wherein the insulating film of the pixel separation section covers a top portion and a side portion of the anti-reflective film.

7. The imaging element according to claim 1, wherein materials for the electrode plug include titanium (Ti)/tungsten (W) and Ti/Ti nitride (N)/W.

8. The imaging element according to claim 1, wherein the through electrode is formed integrally with a polysilicon electrode provided at a second end of the through electrode opposite to the first end of the through electrode.

9. The imaging element according to claim 5, wherein materials for the anti-reflective film include silicon nitride (SiN), hydrofluoroolefin (HfO) and tantalum oxide (TaO).

10. The imaging element according to claim 1, wherein the electrode plug is provided within a groove.

11. An electronic apparatus comprising:
an optical section including a lens;
an imaging element that receives light incident thereon through the optical section, the imaging element comprising:
a plurality of pixels;
a photoelectric conversion film provided on one side of a semiconductor substrate;
a pixel separation section formed in an inter-pixel region around a portion of each of the plurality of pixels; and
a through electrode that transmits a signal, corresponding to an electric charge obtained by photoelectric conversion in the photoelectric conversion film, to a wiring layer formed on another side of the semiconductor substrate, the through electrode being formed in the inter-pixel region outside of the pixel separation section,
wherein the through electrode is connected to a lower electrode of the photoelectric conversion film through an electrode plug, and
wherein the electrode plug has about a same size diameter as the through electrode; and
a signal processing section that processes pixel data outputted from the imaging element.

12. The electronic apparatus according to claim 11, wherein the through electrode is formed from a polysilicon with an impurity.

13. The electronic apparatus according to claim 11, wherein the pixel separation section and the through electrode are formed in such a manner that an insulating film of the pixel separation section and an insulating film covering a periphery of the through electrode make contact with each other.

14. The electronic apparatus according to claim 13, wherein the insulating film of the pixel separation section and the insulating film covering a periphery of the through electrode each covers a portion of the electrode plug.

15. The electronic apparatus according to claim 13, further comprising an anti-reflective film provided on the semiconductor substrate.

16. The electronic apparatus according to claim 15, wherein the insulating film of the pixel separation section covers a top portion and a side portion of the anti-reflective film.

17. The electronic apparatus according to claim 11, wherein materials for the electrode plug include titanium (Ti)/tungsten (W) and Ti/Ti nitride (N)/W.

18. The electronic apparatus according to claim 11, wherein the through electrode is formed integrally with a polysilicon electrode provided at a second end of the through electrode opposite to the first end of the through electrode.

19. The electronic apparatus according to claim 15, wherein materials for the anti-reflective film include silicon nitride (SiN), hydrofluoroolefin (HfO) and tantalum oxide (TaO).

20. The electronic apparatus according to claim 11, wherein the electrode plug is provided within a groove.
